(19) United States
(12) Patent Application Publication
(10) Pub. No.: US 2018/0019576 A1
(43) Pub. Date: Jan. 18, 2018

(54) LASER BEAM COMBINATION APPARATUS

(71) Applicant: BWT Beijing Ltd., Beijing (CN)

(72) Inventors: Weirong GUO, Beijing (CN); Baohua WANG, Beijing (CN); Zhijie GUO, Beijing (CN); Dan XU, Beijing (CN); Lei XU, Beijing (CN); Xiaohua CHEN, Beijing (CN)

(73) Assignee: BWT Beijing Ltd., Beijing (CN)

(21) Appl. No.: 15/588,195

(22) Filed: May 5, 2017

Related U.S. Application Data
(63) Continuation of application No. PCT/CN2016/092696, filed on Aug. 1, 2016.

(30) Foreign Application Priority Data
Jul. 14, 2016 (CN) 201610556293.0

(51) Int. Cl. H01S 5/40; H01S 3/125; H01S 5/14; H01S 5/42; H01S 5/024

(52) U.S. Cl. CPC H01S 5/4012; H01S 5/42; H01S 5/4025; H01S 5/02423; H01S 5/4075; H01S 5/14; H01S 3/125

(57) ABSTRACT

A laser beam combination apparatus includes: a lasers array, an optical turning element, a transformation lens, a dispersion element and an external cavity mirror. The lasers array comprises M rows of lasers, and each row of the lasers comprises N lasers; M×N laser beams output by the lasers array, after passing through the optical turning element, parallel exit, where the N laser beams corresponding to each row of the lasers constitute a coplanar laser beam array, planes where the M laser beam arrays lie are parallel to one another, and planes where two adjacent laser beam arrays lie are spaced apart by a designated distance; the N laser beams in each laser beam array, after going through the convergence by the transformation lens, individually incident on the dispersion element at different angles; and the N laser beams in each laser beam array, after going through the dispersion element, are combined into one beam of output light, and M output beams corresponding to the M laser beam arrays are parallel output through the external cavity mirror.

### CROSS-REFERENCE TO RELATED APPLICATIONS

This application is a continuation of International Application No. PCT/CN2016/092696, filed on Aug. 1, 2016, which is based upon and claims priority to Chinese Patent Application No. 201610556293.0, filed on Jul. 14, 2016, the entire contents of both of which are incorporated herein by reference.

### FIELD

The present disclosure relates to technical field of laser, and specifically to a laser beam combination apparatus.

### BACKGROUND

Laser beam combination technology is a procedure of improving beam quality, increasing output power and improving power density. Commonly-used laser beam combination methods include spectral beam combination, spatial beam combination and polarization beam combination. These laser beam combination methods may be used individually, or multiple different laser beam combination methods may be used in conjunction in some cases.

In a current laser beam combination technology, emitters emitting a plurality of laser beams to be combined, namely, a plurality of lasers are disposed on a base. Usually, due to factors such as the structural limitation of micro-channels and structural limitation of optical alignment systems, lasers in a laser array that can be implemented are spaced apart by a distance somewhat larger than the beam size, and the adjacent lasers cannot be very close. As a result, the gaps in the finally-output combined beams cannot be avoided so that it is difficult to further improve the output power density.

### SUMMARY

In view of the above problems, the present disclosure is proposed to provide a laser beam combination apparatus that overcomes the above problems or at least partially solves the above problems.

According to an aspect of the present disclosure, the present disclosure provides a laser beam combination apparatus, comprising: a lasers array, an optical turning element, a transformation lens, a dispersion element and an external cavity mirror;

the lasers array comprises M rows of lasers, and each row of the lasers comprises N lasers, wherein both M and N are positive integers greater than 1;

M×N laser beams output by the lasers array, after passing through the optical turning element, parallel exit, wherein the N laser beams corresponding to each row of the lasers constitute a coplanar laser beam array, planes where the M laser beam arrays lie are parallel to one another, and planes where two adjacent laser beam arrays lie are spaced apart by a designated distance;

the M laser beam arrays are incident on the transformation lens, and the N laser beams in each laser beam array, after being converged by the transformation lens, incident on the dispersion element at different angles; and

the N laser beams in each laser beam array, after going through the dispersion element, are combined into one beam of output light, and M output beams corresponding to the M laser beam arrays are parallel output through the external cavity mirror.

Optionally, the external cavity mirror is a partially reflective and partially transmitting optical element; and

the M output beams corresponding to the M laser beam arrays transmit through the external cavity mirror and are parallel output, and the N laser beams in each output beam are reflected by the external cavity mirror, and then return along an original optical path to the corresponding laser, respectively.

Optionally, the laser beams output by the lasers in the lasers array undergo the same optical path during the process of being transmitted to the transformation lens.

Optionally, the apparatus further comprises: a base; and

the base is a stepped structure, and the lasers array is disposed on the base; the base has M steps, the N lasers are disposed on each step, and the N lasers are arranged in one row in the direction parallel to a long side of the step.

Optionally, water-cooling channels are processed inside the base to allow cooling water to circulate in the water-cooling channels.

Here, at least one laser in the lasers array is a diode laser emitter. Optionally, each laser in the lasers array is a diode laser emitter.

Optionally, the apparatus further comprises: M×N fast-axis collimation lenses and M×N slow-axis collimation lenses corresponding to the M×N lasers in the lasers array; and

the laser beams output by each of the lasers, after going through the corresponding fast-axis collimation lens and slow-axis collimation lens, incident on the optical turning element.

Optionally, the apparatus further comprises a beam expander or a beam compressor; and

the beam expander or the beam compressor is located between the slow-axis collimation lens and the optical turning element, or the beam expander or the beam compressor is located between the optical turning element and the transformation lens.

Optionally, the dispersion element comprises a reflection grating or a transmitting grating.

Optionally, the optical turning element comprises: a reflection planar mirror and/or a reflection prism.

As can be seen from the above, in the technical solution according to the present disclosure, M×N laser beams output by the lasers array, after passing through the optical turning element, parallel exit onto the transformation lens, and after being converged by the transformation lens, the N laser beams corresponding to each row of the lasers respectively incident on the dispersion element at different angles. According to the dispersing action of the dispersion element, the laser with the corresponding wavelength is selected from the range of the wavelengths of each beam of laser so that the N laser beams with different wavelengths are selected from the N laser beams output from each row of the lasers, the N laser beams with different wavelengths are combined at the same angle into one beam of output light which incidents on the external cavity mirror, and M beams of output light corresponding to the M rows of lasers are parallel output through the external cavity mirror, to thereby completely spectral beam combine M×N laser beams output by the lasers array in the slow axis direction of laser and spatially combine beams in the fast axis direction of laser. The present solution is simple in principle, reasonable in configuration and highly implementable. Due to use of the optical turning structure, the drawback of many dark gaps in spots after beam combination in the prior art of beam combination technology may be overcome, and the lasers in the lasers array need not to be closely arranged, and more efficient laser beam combination is implemented while the heat dissipation performance of the lasers array is improved.

The above description is only the generalization of the technical solutions of the present disclosure. The present disclosure may be implemented according to the content of the description in order to make the technical means of the present disclosure more apparent. Specific embodiments of the present disclosure are exemplified to make the above and other objects, features and advantages of the present disclosure more apparent.

### BRIEF DESCRIPTION OF DRAWINGS

Various other advantages and merits will become apparent to those skilled in the art by reading through the following detailed description of preferred embodiments. Figures are only intended to illustrate the preferred embodiments, not to limit the present disclosure. In all the figures, the same reference number denotes the same part. In the figures:

FIG. 1A is a schematic view of a laser beam combination apparatus according to a first embodiment of the present disclosure;

FIG. 1B is a side view of a laser beam combination apparatus according to a first embodiment of the present disclosure;

FIG. 1C is a top view of a laser beam combination apparatus according to a first embodiment of the present disclosure;

FIG. 2A is a schematic view of the spots of the laser beams output by a lasers array on a transformation lens according to a first embodiment of the present disclosure;

FIG. 2B is a schematic view of spots after the laser beams output by a lasers array pass through an external cavity mirror according to a first embodiment of the present disclosure;

FIG. 3A is a schematic view of a base of a laser beam combination apparatus according to a first embodiment of the present disclosure;

FIG. 3B is a side view of a base of a laser beam combination apparatus according to a first embodiment of the present disclosure;

FIG. 3C is a top view of a base of a laser beam combination apparatus according to a first embodiment of the present disclosure; and

FIG. 4 is a schematic view of a laser beam combination apparatus according to a second embodiment of the present disclosure.

### DETAILED DESCRIPTION OF PREFERRED EMBODIMENTS

Exemplary embodiments of the present disclosure will be described in more detail with reference to the figures. Although the figures show the exemplary embodiments of the present disclosure, it should be appreciated that the present disclosure may be implemented in various forms and should not be limited by the embodiment described here. On the contrary, these embodiments are provided to make the present disclosure more apparent and entirely convey the scope of the present disclosure to those skilled in the art.

x axis, y axis and z axis are established to constitute a right-hand spatial right-angle coordinate system x-y-z, wherein x axis is the transverse axis, z axis is the longitudinal axis and y axis is the vertical axis. A spatial beam combination apparatus and system according to the present disclosure will be described according to the right-hand spatial right angle coordinate system. In the following embodiments, the longitudinal axis corresponds to the fast axis direction of the laser beam, and the transverse axis corresponds to the slow axis direction of the laser beam.

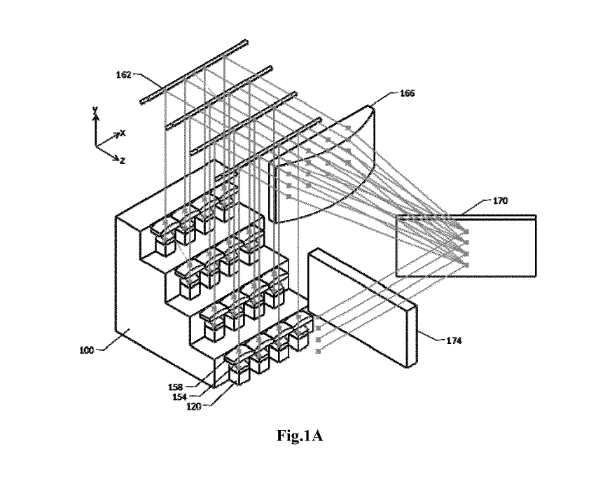

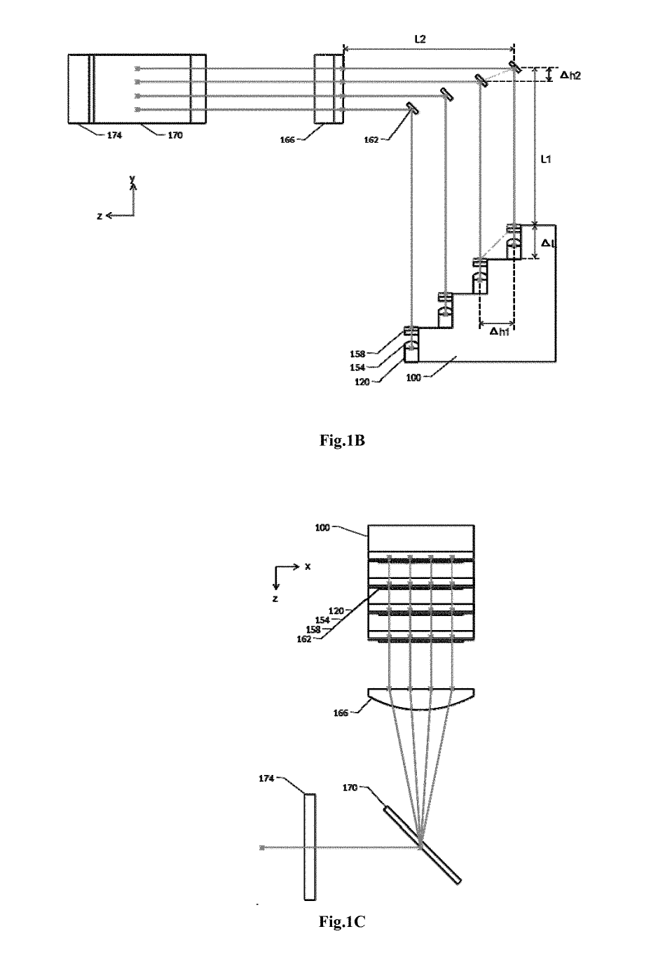

FIG. 1A is a schematic view of a laser beam combination apparatus according to a first embodiment of the present disclosure. As shown in FIG. 1A, the apparatus comprises a base 100, a lasers array, a fast-axis collimation lens 154, a slow-axis collimation lens 158, an optical turning element 162, a transformation lens 166, a dispersion element 170 and an external cavity mirror 174, wherein the lasers array comprises four rows of lasers, each row of lasers are disposed on a step of the base 100, each row of lasers comprises four lasers 120, the four lasers 120 in each row of lasers are arranged in a row in the direction of a long side of the step of the base 100 (the x-axis direction), each laser 120 corresponds to one fast-axis collimation lens 154 and one slow-axis collimation lens 158, and each row of lasers corresponds to one optical turning element 162.

In the present embodiment, the base 100 is a heat sink base to reduce the temperature of the lasers 120, the laser 120 is a diode laser emitter, the optical turning element 162 is a reflection plane mirror, the transformation lens 166 is a cylindrical lens, and the dispersion element 170 is a transmitting grating. The laser beams output by each of the lasers 120 in turn pass through the fast-axis collimation lens 154 and the slow-axis collimation lens 158 corresponding to the laser 120. The fast-axis collimation lens 154 collimates the output laser beams in the fast axis direction of the laser, the slow-axis collimation lens 158 collimates the output laser beams in the slow axis direction of the laser. The laser beams, after having gone through fast axis collimation and slow axis collimation, incident on the corresponding optical turning element 162, and the optical turning element 162 changes its direction. Specifically, the four laser beams output by each row of lasers in the lasers array incident on the optical turning element 162 corresponding to the row of lasers, the optical turning element 162 changes the directions of the four laser beams. And the 16 laser beams output by the lasers array, after being redirected by the optical turning element, propagate in directions parallel to one another. Furthermore, the four laser beams corresponding to each row of the lasers are parallel and coplanar to constitute a laser beam array. The four planes where the four laser beam arrays corresponding to the four rows of lasers lie are parallel to one another, and the distances between the planes where the adjacent laser beam arrays lie may be adjusted through the optical turning element 162.

FIG. 1B is a side view of a laser beam combination apparatus according to a first embodiment of the present disclosure, namely, a schematic view of the laser beam combination apparatus on the y-z plane. As shown in FIGS. 1A-1B, the laser beams output by each row of the lasers, after being redirected by the optical turning element 162, are parallel to each other and coplanar and constitutes a laser beam array. The four planes where the four laser beam arrays corresponding to the four rows of lasers lie are parallel to one another, and the distances between the planes where the adjacent laser beam arrays lie are Δh2. The propagation distance of the laser beams emitted by the row of lasers located on the uppermost step of the base 100 from the slow-axis collimation lens 158 to incident into the optical turning element 162 corresponding to the row of lasers is L1. The propagation distance of the laser beams emitted by the lasers arrays corresponding to each row of the lasers from direction changing and output of the optical turning element 162 to incident into the transformation lens 166 is L2. The height (in the y-axis direction) of each step of the base 100 is ΔL, that is, the distance between adjacent rows of lasers located on the base 100 in the y-axis direction is ΔL, and the width (in the z-axis direction) of each step of the base 100 is Δh1, namely, the distance between adjacent rows of lasers located on the base 100 in the z-axis direction is Δh1. In the present embodiment, Δh2=1 mm, L1=20 mm, L2=20 mm, Δh1=3 mm, and ΔL=4 mm, and a 3 mm×4 mm side surface shape of the step provides a sufficient space for placing water-cooling channels 180 in the interior of the base 100.

It may be appreciated that an optical path of laser emitted by the row of lasers located on the uppermost step of the base 100 from collimation and output to incidence to the transformation lens 166 is L1+L2=40 mm, and the optical path of the lasers emitted by the row of lasers located on the lowermost step of the base 100 from collimation and output to incident on the transformation lens 166 is:

(L1+3×ΔL−3×Δh2)+(l2−3×Δh1)=(20 mm+3×4 mm−3×1 mm)+(20 mm−3×3 mm)=40 mm

Likewise, the optical paths of the lasers emitted by two rows of lasers located on two intermediate steps of the base 100 from collimation and output to incident on the transformation lens 166 are 40 mm respectively.

As can be seen from the above, the structure of the laser beam combination apparatus provided by the present embodiment maintains that the laser beams output by different lasers 120 in the lasers array undergo the same optical path from laser array to arrival at the transformation lens 166 so that the spots of the lasers incident on the transformation lens 166 are approximate in size, which facilitates improvement of laser beam combination efficiency and obtains higher power density through beam combination. Furthermore, the spacing between the planes where adjacent laser beam arrays lie when the laser beam array corresponding to each row of the lasers reaches the transformation lens 166 is only 1 mm so that the laser beams output by different rows of lasers are closer, and the total distance of the laser beams output by the four rows of lasers in they axis is about 4 mm.

FIG. 1C is a top view of a laser beam combination apparatus according to a first embodiment of the present disclosure, namely, a schematic view of the laser beam combination apparatus in the x-y plane. As shown in FIGS. 1A-1C, after passing through the optical turning element 162, the laser beam array corresponding to each row of the lasers incident on the transformation lens 166. With the focal distance and the position of the transformation lens 166 being set, the transformation lens 166 converges the four laser beams corresponding to each row of the lasers, respectively, and thus the laser beams output by each of the lasers 120 may become a laser beam with a smaller divergence angle after passing through the transformation lens 166. The laser beams output by the lasers 120 among each row of the lasers at different positions in the x axis, after passing through the transformation lens 166, irradiate on the dispersion element 170 at different angles. The laser beams output by the lasers 120 among different rows of lasers at the same position in the x axis, after passing through the transformation lens 166, irradiate on the dispersion element 170 at the same angle. The dispersion element 170 and the external cavity mirror 174 constitute an external cavity. As for each beam of laser incident thereon, the dispersion element 170 selects the laser with the corresponding wavelength from the wavelength range of the beam of laser according to dispersion principles and the incident angle of the beam of laser, and outputs at a designated angle. Since the four laser beams corresponding to each row of the lasers are incident on the dispersion element 170 at different angles, the dispersion element 170, upon dispersing the four beams of laser, respectively selects laser with respective wavelength from the four beams of laser, the selected wavelengths corresponding to the four laser beams being different, and outputs the laser beams with the four wavelengths corresponding to the four laser beams at a designated angle.

It can be seen that the four laser beams corresponding to each row of the lasers, after going through the dispersion element 170, are combined into one output beam, and the output beam is the result of spectral beam combination of the four beams of laser. The four laser beams corresponding to each row of the lasers, after going through the dispersion element 170, are all combined into one beam of output light, and then the dispersion element 170 outputs the output light obtained through spectral combination of the four beams. The four beams of output light are output after passing through the external cavity mirror 174. As stated previously, the distance of the laser beam arrays corresponding to different rows of lasers in the y-axis direction is adjusted via the optical turning element 162, so that the laser beam arrays output by different rows of lasers get closer. Hence, the four beams of output light output at this time are arranged very closely so that the lasers corresponding to different rows of lasers are spatially combined in the y-axis direction. Furthermore, the external cavity mirror 174 is a partially reflective and partially transmitting optical element, and when each beam of output light corresponding to the result of spectral beam combination of the laser beams output by each row of the lasers is incident on the external cavity mirror 174, part of the light is output by the external cavity mirror 174 in a transmitting manner, and the remaining part of light is reflected by the external cavity mirror 174. In the present embodiment, as for the output light including the lasers with four wavelengths, the reflection of the external cavity mirror 174 enables the lasers with each of the wavelengths in the output light to return along the original optical path to the corresponding laser 120, that is, feeds part of the powers of the wavelengths satisfying conditions back to the corresponding laser 120, thereby functioning to select a wavelength, so that the wavelengths of the laser beams output by the lasers 120 among each row of the lasers at different positions in the x axis are slightly different. It can be seen that the external cavity formed by the external cavity mirror 174 and the dispersion element 170 has a certain wavelength selectivity, which locks corresponding wavelengths in the range of the wavelengths output by respective lasers 120, narrows down the spectral width so that the respective lasers 120 can output different wavelengths, and improves stability during laser beam combination.

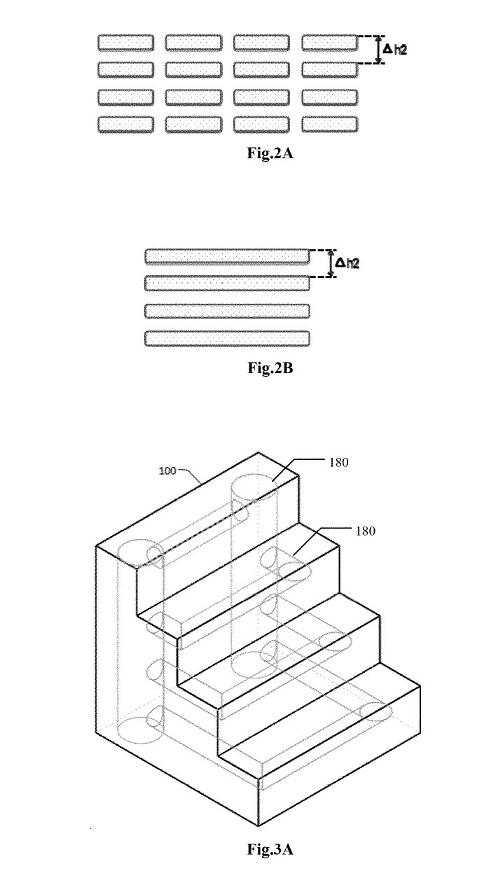

FIG. 2A is a schematic view of the spots of the laser beams output by a lasers array on a transformation lens according to a first embodiment of the present disclosure. As shown in FIG. 2A, after the laser beams output by the lasers array are redirected by the optical turning element 162, the laser beam arrays corresponding to adjacent rows of lasers are arranged relatively closely in the y-axis direction with the spacing of Δh2. As stated above, Δh2 is only about 1 mm, which achieves a relatively ideal spatial beam combination of the lasers corresponding to different rows of lasers in the y-axis direction. FIG. 2B is a schematic view of spots after the laser beams output by a lasers array pass through an external cavity mirror according to a first embodiment of the present disclosure. As shown in FIG. 2B, the four laser beams corresponding to each row of the lasers, after being subject to spectral beam combination, are combined into one beam of output light, the output lights corresponding to adjacent rows of lasers are arranged relatively closely in the y-axis direction, and the adjacent output light are spaced apart by the distance Δh2 in the y axis. As stated above, Δh2 is only about 1 mm, which achieves a relatively ideal spatial beam combination of the lasers corresponding to different rows of lasers in the y-axis direction.

It can be seen that the laser beam combination apparatus according to the present embodiment performs spectral beam combination for the laser beams output by each row of the lasers in the lasers array, and performs spatial beam combination for the laser beams output by different rows of lasers, to achieves a relatively ideal laser beam combination effect and obtain a high power output result.

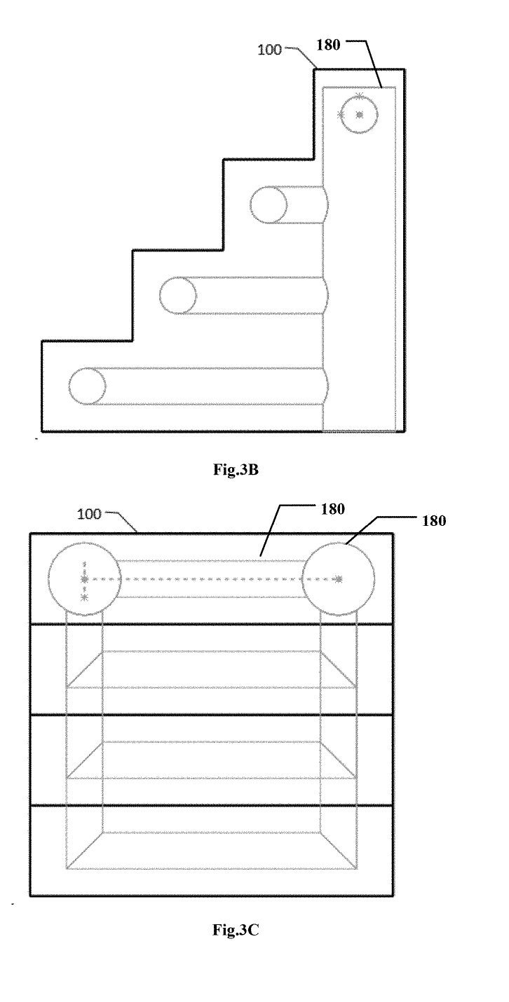

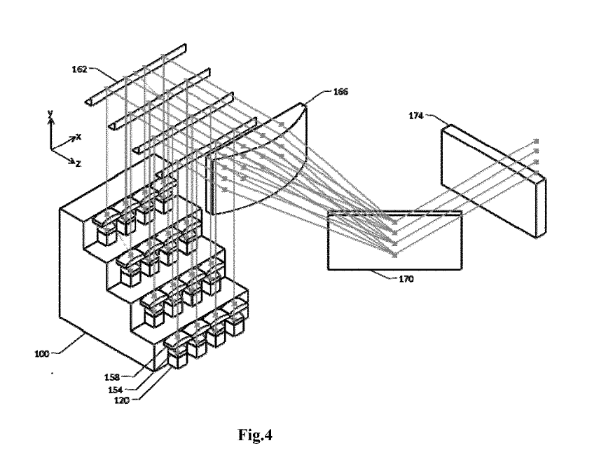

FIG. 3A is a schematic view of a base of a laser beam combination apparatus according to a first embodiment of the present disclosure. FIG. 3B is a side view of a base of a laser beam combination apparatus according to a first embodiment of the present disclosure, namely, a schematic view in the y-z plane, and FIG. 3C is a top view of a base of a laser beam combination apparatus according to a first embodiment of the present disclosure, namely, a schematic view in the x-z plane. As shown in FIGS. 3A-3C, the base 100 in the laser beam combination apparatus in the present embodiment is a stepped structure, a plurality of water-cooling channels 180 are processed in the interior of the base 100, cooling water is provided in the water-cooling channels 180 to circulate to reduce the temperature of the lasers 120 disposed on the base 100, the plurality of water-cooling channels 180 processed in the interior of the base 100 include a water inlet channel and a water outlet channel to allow the cooling water to flow in and flow out, and both ends of the remaining water-cooling channels 180 are respectively communicated with the water inlet channel and the water outlet channel. It can be seen that the base 100 designed as a stepped structure in the present embodiment, with water-cooling channels 180 being processed in the interior of the base 100 without affecting laser placement positions, facilitates the close arrangement of different rows of lasers, facilitates the reduction of the overall size of the laser beam combination apparatus, and improves the efficacy of the laser beam combination apparatus.

FIG. 4 is a schematic view of a laser beam combination apparatus according to a second embodiment of the present disclosure. As shown in FIG. 4, the apparatus comprises a base 100, a lasers array, a fast-axis collimation lens 154, a slow-axis collimation lens 158, an optical turning element 162, a transformation lens 166, a dispersion element 170 and an external cavity mirror 174, wherein the lasers array comprises four rows of lasers, each row of the lasers are disposed on a step of the base 100, each row of the lasers comprises four lasers 120, the four lasers 120 in each row of the lasers are arranged in a row in the direction of a long side of the step of the base 100 (the x-axis direction), each laser 120 corresponds to one fast-axis collimation lens 154 and one slow-axis collimation lens 158, and each row of the lasers corresponds to one optical turning element 162.

In the present embodiment, the base 100 is a heat sink base to reduce the temperature of the lasers 120, the laser 120 is a diode laser emitter, the optical turning element 162 is a reflection prism, the transformation lens 166 is a cylindrical lens, and the dispersion element 170 is a reflection grating. The laser beams output by each of the lasers 120 in turn pass through the fast-axis collimation lens 154 and the slow-axis collimation lens 158 corresponding to the laser 120, the fast-axis collimation lens 154 collimates the output laser beams in the fast axis direction of the laser, the slow-axis collimation lens 158 collimates the output laser beams in the slow axis direction of the laser. The laser beams, after having gone through fast axis collimation and slow axis collimation, incident on the corresponding optical turning element 162, and the optical turning element 162 changes its direction. Specifically, the four laser beams output by each row of the lasers in the lasers array incident on the optical turning element 162 corresponding to the row of lasers, the optical turning element 162 changes the directions of the four laser beams. And the 16 laser beams output by the lasers array, after redirected by the optical turning element 162, propagate in directions parallel to one another. Furthermore, the four laser beams corresponding to each row of the lasers are parallel and coplanar to constitute a laser beam array. The four planes where the four laser beam arrays corresponding to the four rows of lasers lie are parallel to one another, and the distances between the planes where the adjacent laser beam arrays lie may be adjusted through the optical turning element 162.

In the present embodiment, the distances between the planes where the adjacent laser beam arrays lie are Δh2. The propagation distance of the laser beams emitted by the row of lasers located on the uppermost step of the base 100 from the slow-axis collimation lens 158 output to incident to the optical turning element 162 corresponding to the row of lasers is L1, the propagation distance of the laser beams emitted by the lasers arrays corresponding to each row of the lasers from direction changing and output of the optical turning element 162 to incident into the transformation lens 166 is L2, the height (in the y-axis direction) of each step of the base 100 is ΔL, that is, the distance between adjacent rows of lasers located on the base 100 in the y-axis direction is ΔL, and the width (in the z-axis direction) of each step of the base 100 is Δh1, namely, the distance between adjacent rows of lasers located on the base 100 in the z-axis direction is Δh1. Specifically, Δh2=1 mm, L1=20 mm, L2=20 mm, Δh1=3 mm, and ΔL=4 mm, and a 3 mm×4 mm side surface shape of the step provides a sufficient space for placing water-cooling channels 180 in the interior of the base 100.

As can be obtained from calculation, the structure of the laser beam combination apparatus provided by the present embodiment maintains that the laser beams output by different lasers 120 in the lasers array undergo the same optical path when arriving at the transformation lens 166 so that the spots of the lasers incident on the transformation lens 166 are approximate in size, which facilitates improvement of laser beam combination efficiency and obtains higher power density to a maximum degree through beam combination. Furthermore, the spacing between the planes where adjacent laser beam arrays lie when the laser beam array corresponding to each row of the lasers reaches the transformation lens 166 is only 1 mm so that the laser beams output by different rows of lasers are closer, and the total distance of the laser beams output by the four rows of lasers in the y axis is about 4 mm.

After passing through the optical turning element 162, the laser beam array corresponding to each row of the lasers incident on the transformation lens 166. With the focal distance and the position of the transformation lens 166 being set, the transformation lens 166 converges the four beams of laser corresponding to each row of the lasers, respectively, and thus the laser beams output by each of the lasers 120 may become a laser beam with a smaller divergence angle after passing through the transformation lens 166. The laser beams output by the lasers 120 among each row of the lasers at different positions in the x axis, after passing through the transformation lens 166, irradiate on the dispersion element 170 at different angles. The laser beams output by the lasers 120 among different rows of lasers at the same position in the x axis, after passing through the transformation lens 166, irradiate on the dispersion element 170 at the same angle. The dispersion element 170 and the external cavity mirror 174 constitute an external cavity. As for each beam of laser incident thereon, the dispersion element 170 selects the laser with the corresponding wavelength from the wavelength range of the beam of laser according to dispersion principles and the incident angle of the beam of laser, and outputs in a reflection manner at a designated angle. Since the four laser beams corresponding to each row of the lasers incident on the dispersion element 170 at different angles, the dispersion element 170, upon dispersing the four beams of laser, respectively selects laser with respective wavelength from the four beams of laser, the selected wavelengths corresponding to the four laser beams being different, and outputs the laser beams with the four wavelengths corresponding to the four laser beams at a designated angle.

In the present embodiment, the schematic views of the spots of the lasers in the laser beam combination apparatus are identical with FIGS. 2A-2B above, and the embodiment in which water-cooling channels 180 are processed in the interior of the base 100 is the same as what is shown in FIGS. 3A-3C above. No detailed description will be presented here because the above has already given detailed description.

In contrast, the prior art employs a solution in which a lasers array is disposed on a base with a side (the y-z plane) in a form of square waveform, each row of the lasers are placed on a recessed platform on the base, and two adjacent rows of lasers are spaced apart by a raised platform. Since a space needs to be reserved in each raised platform in the base to arrange water-cooling channels, the height of each raised platform is unlikely to be less than 1.8 mm even if small channels are employed. Correspondingly, it is difficult for the spacing between the laser beams output by different rows of lasers to be less than 1.8 mm. Furthermore, the prior art does not employ the optical turning element to change direction so that the overall height of the light beams emitted by four rows of diode laser emitter is no less than 7.2 mm, the spacing of the finally-output spots in the y-axis direction is larger, and a desirable beam combination effect is hard to implement. As can be seen from the above, as compared with the laser beam combination solution in the prior art, the laser beam combination apparatus according to the above first embodiment and second embodiment may provide spots which are smaller in overall size and higher in overall brightness.

To conclude, in the technical solution according to the present disclosure, M×N laser beams output by the lasers array, after passing through the optical turning element, parallel exit onto the transformation lens, and after going through the focusing of the transformation lens, the N laser beams corresponding to each row of the lasers individually incident on the dispersion element at different angles. According to the dispersing action of the dispersion element, the laser with the corresponding wavelength is selected from the range of the wavelengths of each beam of laser so that the N laser beams with different wavelengths are selected from the N laser beams output from each row of the lasers, the N laser beams with different wavelengths are combined at the same angle into one beam of output light which exits to the external cavity mirror, and M beams of output light corresponding to the M rows of lasers are parallel output through the external cavity mirror, to thereby complete the spectral beam combination of the M×N laser beams output by the lasers array in the slow axis direction of laser and the spatial beam combination in the fast axis direction of laser. The present solution is simple in principle, reasonable in configuration and highly implementable. Due to the use of the direction-changing structure, the drawback of many dark gaps in the spots after beam combination in the prior art of beam combination technology may be overcome, and the lasers in the lasers array need not to be closely arranged, and more efficient laser beam combination is implemented while the heat dissipation performance of the lasers array is improved.

What are described above are only preferred embodiments of the present disclosure and not intended to limit the protection scope of the present disclosure. Any modifications, equivalent substitutions and improvements made within the spirit and principle of the present disclosure are all included in the protection scope of the present disclosure.

What is claimed is:

1. A laser beam combination apparatus, comprising: a lasers array, an optical turning element, a transformation lens, a dispersion element, and an external cavity mirror;
the lasers array comprises M rows of lasers, and each row of the lasers comprises N lasers, wherein both M and N are positive integers greater than 1;
M×N laser beams output by the lasers array, after passing through the optical turning element, parallel exit, wherein the N laser beams corresponding to each row of the lasers constitute a coplanar laser beam array, planes where M laser beam arrays lie are parallel to one another, and planes where two adjacent laser beam arrays lie are spaced apart by a designated distance;
the M laser beam arrays incident on the transformation lens, and the N laser beams in each laser beam array, after converged by the transformation lens, individually incident on the dispersion element at different angles; and
the N laser beams in each laser beam array, after going through the dispersion element, are combined into an output beam, and M output beams corresponding to the M laser beam arrays are parallel output through the external cavity mirror.

2. The apparatus according to claim 1, wherein the external cavity mirror is a partially reflective and partially transmitting optical element; and
the M output beam corresponding to the M laser beam arrays transmit through the external cavity mirror and are parallel output, and the N laser beams in each output beam are reflected by the external cavity mirror, and then individually return along an original optical path to the corresponding laser.

3. The apparatus according to claim 1, wherein the laser beams output by each laser in the lasers array undergo the same optical path during the process of being transmitted to the transformation lens.

4. The apparatus according to claim 1, wherein the apparatus further comprises: a base; and
the base is a stepped structure, and the lasers array is disposed on the base; the base has M steps, the N lasers are disposed on each step, and the N lasers are arranged in one row in the direction parallel to a long side of the step.

5. The apparatus according to claim 4, wherein the base comprises water-cooling channels inside the base, the water-cooling channels configured to allow cooling water to circulate in the water-cooling channels.

6. The apparatus according to claim 1, wherein at least one laser in the lasers array is diode laser emitter.

7. The apparatus according to claim 6, wherein the apparatus further comprises:
M×N fast-axis collimation lenses and M×N slow-axis collimation lenses corresponding to the M×N lasers in the lasers array; and
laser beams output by each of the lasers, after going through the corresponding fast-axis collimation lens and the slow-axis collimation lens, incident on the optical turning element.

8. The apparatus according to claim 7, further comprising a beam expander or a beam compressor; and
the beam expander or the beam compressor is located between the slow-axis collimation lens and the optical turning element, or the beam expander or the beam compressor is located between the optical turning element and the transformation lens.

9. The apparatus according to claim 1, wherein the dispersion element comprises a reflection grating or a transmitting grating.

10. The apparatus according to claim 1, wherein the optical turning element comprises: a reflection planar mirror.

11. The apparatus according to claim 1, wherein the optical turning element comprises: a reflection prism.
